(19) United States
(12) Patent Application Publication
(10) Pub. No.: US 2004/0238821 A1
(43) Pub. Date: Dec. 2, 2004

(54) CAPACITIVE SEMICONDUCTOR PRESSURE SENSOR

(76) Inventor: Chien-Sheng Yang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/708,199

(22) Filed: Feb. 16, 2004

(30) Foreign Application Priority Data
May 28, 2003 (TW) 092114483

(51) Int. Cl. H01L 29/04

(52) U.S. Cl. 257/72

(57) ABSTRACT

A capacitive semiconductor pressure sensor includes a non-single-crystal-silicon-based substrate, a conductive movable polysilicon diaphragm, a polysilicon supporter positioned on the non-single-crystal-silicon-based substrate for fixing two ends of the polysilicon diaphragm and forming a sealed cavity between the polysilicon diaphragm and the non-single-crystal-silicon-based substrate, a stationary electrode positioned on the non-single-crystal-silicon-based substrate and below the polysilicon diaphragm, and a thin film transistor (TFT) control circuit positioned on the non-single-crystal-silicon-based substrate and electrically connected to the plate capacitor. The stationary electrode and the polysilicon diaphragm together constitute a plate capacitor, and the stationary electrode and the polysilicon diaphragm respectively function as a lower electrode and an upper electrode of the plate capacitor.

### BACKGROUND OF INVENTION

1. Field of the Invention

The present invention relates to a pressure sensor, and more specifically, to a capacitive semiconductor pressure sensor formed on a non-single-crystal-silicon-based substrate for reducing production cost.

2. Description of the Prior Art

Air pressure or hydraulic measurements are important in industrial control. Currently, a pressure sensor in common use includes a piezoresistive pressure sensor, a piezo-electric pressure sensor, a capacitive pressure sensor, a potentiometer pressure sensor, an inductive-bridge pressure sensor, a strain gauge pressure sensor, and a semi-conductor pressure sensor. Among the above-mentioned pressure sensors, the capacitive pressure sensor has good detection sensitivity and high stability to an ambient environment so that it becomes more and more popular in an industrial market.

Additionally, because sizes of the pressure sensors are reduced gradually, a micromachining technology is developed to manufacture various microsensors and microactuators that are integrated with micro electronic circuits to form a microsystem, which is generally called as a micro electro-mechanical system (MEMS). The MEMS has an extremely small size and can be manufactured by utilizing batch production for reducing a production cost. In addition, the MEMS and a signal processing circuit can be simultaneously formed on a silicon wafer for forming a monolithic device, which can reduce a distance between a pressure sensor and a signal processing circuit and that is quite important for a pressure sensor. As a pressure sensor outputs a signal, the signal is firstly amplified by a signal processing circuit for preventing the signal from being disturbed by an ambient electromagnetic field, and the signal can be analog-to-digital(A/D) converted by the signal processing circuit and be transmitted to a central processing unit. Therefore, as the distance between the pressure sensor and the signal processing circuit is reduced, signal reliability can be greatly improved, and interconnecting lines and loads of central control systems can be effectively decreased. As a result, the pressure sensor that is manufactured by use of MEMS is developed rapidly due to its advantages of good detection sensitivity and a low production cost.

Please refer to FIG. 1. FIG.1 is a sectional view of a conventional capacitive semiconductor pressure sensor 10. As shown in FIG. 1, the capacitive semiconductor pressure sensor 10 mainly comprises a semiconductor substrate 12, such as a single-crystal silicon substrate or a silicon on insulator (SOI) substrate, an epitaxial-silicon diaphragm 14, an epitaxial-silicon base 16 formed on the semiconductor substrate 12 for fixing two ends of the diaphragm 14 and forming a sealed cavity 18 between the diaphragm 14 and the semiconductor substrate 12, and a doped region 20 positioned in the semiconductor substrate 12 and under the diaphragm 14. Generally, the diaphragm 14 functions as an upper electrode or a movable electrode, the doped region 20 is used as a lower electrode or a stationary electrode, and the diaphragm 14 and the doped region 20 together constitute a plate capacitor. Additionally, the capacitive semiconductor pressure sensor 10 further comprises a control circuit 22, such as a complementary metal-oxide semiconductor (CMOS) control circuit, positioned in the base 16 or on the semiconductor substrate 12. The CMOS control circuit 22 is electrically connected to the plate capacitor and is mainly used to receive, process, and transmit signals output form the plate capacitor.

When a pressure to be measured is exerted on the diaphragm 14, or a pressure difference is generated between the inside and the outside of the diaphragm 14, a central portion of the diaphragm 14 will be deformed and a capacitance of the plate capacitor will be altered concurrently. Accordingly, the pressure sensor 10 can utilize the CMOS control circuit 22 to detect variations of an electrostatic capacitance of the plate capacitor for obtaining variations of pressure. In addition, an equation for calculating the electrostatic capacitance of the plate capacitor is C=μA/d, wherein μ is a dielectric constant of a dielectric material filled in the sealed cavity 18, A is an area of a plate that is the diaphragm 14 or the doped region 20, and d is a distance between the diaphragm 14 and the doped region 20. Furthermore, a relationship between a variation of the electrostatic capacitance (ΔC=C−C₀) and the pressure is F=PA=kd₀(ΔC)/C₀, wherein F is an elastic force acted on the pressure sensor 10, k is an elastic constant, d₀ is an initial distance between two plates of the plate capacitor, and C₀ is an initial capacitance of the plate capacitor. Noticeably, if the dielectric constant of the dielectric material filled in the sealed cavity 18 always varies, the pressure sensor 10 cannot work regularly when it is used to detect pressure. Accordingly, it is preferred to hold the inside of the sealed cavity 18 at a vacuum for making the pressure sensor 10 function well. Moreover, since the capacitance of the plate capacitor is only relative to physical parameters, the pressure sensor 10 can be formed with a material having a low thermal expansion coefficient for improving its detection sensitivity.

As described above, the semiconductor substrate 12, the diaphragm 14, and the base 16 are composed of single crystal silicon or epitaxial silicon, so that the conventional capacitive semiconductor pressure sensor 10 has good detection sensitivity. However, costs of silicon wafers and epitaxial silicon are so high that it costs a lot to form the conventional pressure sensor 10. As a result, it is an important issue to manufacture a pressure sensor with a low production cost and a high quality.

### SUMMARY OF INVENTION

It is therefore a primary objective of the claimed invention to provide a capacitive semiconductor pressure sensor with a low production cost.

According to the claimed invention, a capacitive semiconductor pressure sensor is provided. The capacitive semiconductor pressure sensor includes a non-single-crystal-silicon-based substrate, a conductive movable polysilicon diaphragm, a polysilicon supporter positioned on the non-single-crystal-silicon-based substrate for fixing two ends of the polysilicon diaphragm and forming a sealed cavity between the polysilicon diaphragm and the non-single-crystal-silicon-based substrate, a stationary electrode positioned on the non-single-crystal-silicon-based substrate and below the polysilicon diaphragm, and a thin film transistor (TFT) control circuit positioned on the non-single-crystal-silicon-based substrate and electrically connected to the plate capacitor. The stationary electrode and the polysilicon diaphragm together constitute a plate capacitor, and the stationary electrode and the polysilicon diaphragm respectively function as a lower electrode and an upper electrode of the plate capacitor.

It is an advantage over the prior art that the capacitive semiconductor pressure sensor of the claimed invention is formed on the non-single-crystal-silicon-based substrate, such as a glass substrate or a quartz substrate, thereby effectively reducing prime costs of raw materials. Additionally, the diaphragm and its supporter of the claimed invention are composed of polysilicon and are formed concurrently for reducing a production cost to meet requirements of markets.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a sectional view of a conventional capacitive semiconductor pressure sensor 10.

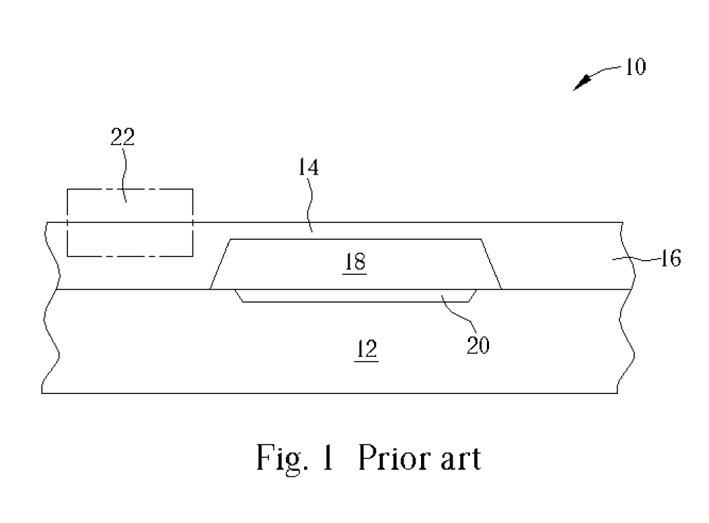

FIG. 2 is a sectional view of a capacitive semiconductor pressure sensor 30 according to the present invention.

### DETAILED DESCRIPTION

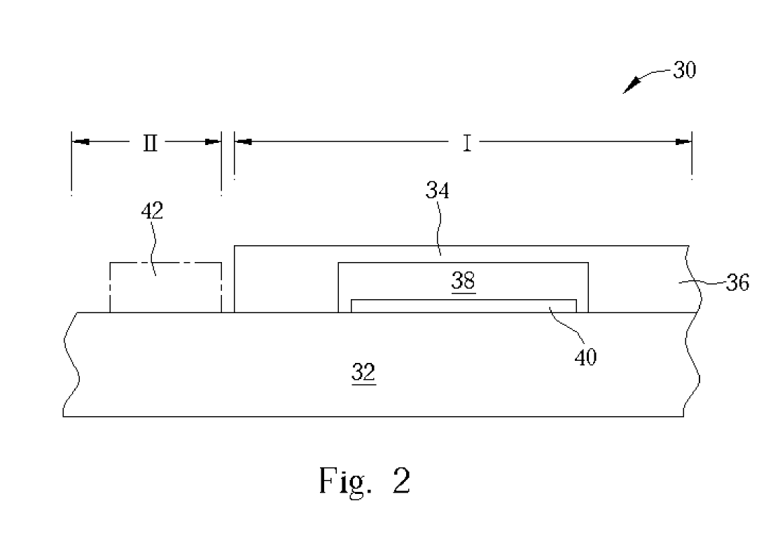

Please refer to FIG. 2. FIG. 2 is a sectional view of a capacitive semiconductor pressure sensor 30 according to the present invention. As shown in FIG. 2, the capacitive semiconductor pressure sensor 30 mainly comprises a non-single-crystal-silicon-based substrate 32, a conductive movable polysilicon diaphragm 34, a polysilicon supporter 36 positioned on the non-single-crystal-silicon-based substrate 32 for fixing two ends of the polysilicon diaphragm 34 and forming a sealed cavity 38 between the polysilicon diaphragm 34 and the non-single-crystal-silicon-based substrate 32, a stationary electrode 40 positioned on the non-single-crystal-silicon-based substrate 32 and under the polysilicon diaphragm 34, and a control circuit 42, such as a thin film transistor (TFT) control circuit, positioned on the non-single-crystal-silicon-based substrate 32. Additionally, the polysilicon diaphragm 34 and the stationary electrode 40 together constitute a plate capacitor of the pressure sensor 30, and the polysilicon diaphragm 34 functions as an upper electrode while the stationary electrode 40 is used as a lower electrode. The thin film transistor (TFT) control circuit 42 is electrically connected to the plate capacitor and is used to receive, process, and transmit signals output from the plate capacitor.

Likewise, the polysilicon diaphragm 34 of the capacitive semiconductor pressure sensor 30 functions as a sensing device. As a pressure to be measured is exerted on the polysilicon diaphragm 34, a central portion of the polysilicon diaphragm 34 is deformed and depressed due to the pressure, thus altering a relative location between the polysilicon diaphragm 34 and the stationary electrode 40 and simultaneously changing a capacitance of the plate capacitor.Accordingly, a pressure to be measured can be obtained through detecting a variation of the electrostatic capacitance of the plate capacitor.

In the preferred embodiment of the present invention, the non-single-crystal-silicon-based substrate 32 is composed of glass. Because the glass substrate 32 has a low melting point, the TFT control circuit 42 has to be a low temperature polysilicon (LTPS) TFT control circuit, which can be formed at a low temperature, thereby preventing the glass substrate 32 from being damaged due to a high temperature. Additionally, the non-single-crystal-silicon-based substrate 32 can be a quartz substrate in another embodiment of the present invention. Owing to a high melting point of the quartz substrate 32, the TFT control circuit 42 can be a high temperature polysilicon TFT control circuit 42. In addition, the polysilicon diaphragm 34 and the polysilicon supporter 36 can be formed simultaneously or can be formed separately. The polysilicon diaphragm 34 can be doped with several dopants for reducing its resistivity and enhancing its conductivity, and the stationary electrode 40 can be composed of aluminum (Al), titanium (Ti), platinum (Pt), or alloys.

It should be noticed that although the control circuit 42 is formed on the glass substrate 32 in the preferred embodiment of the present invention, the present invention is not confined to that. The control circuit 42 also can be formed on a printed circuit board (PCB) (not shown) and be electrically connected to the plate capacitor via a flexible printed circuit (FPC) board (not shown). Alternatively, the control circuit 42, maybe including a plurality of integrated circuit (IC) chips, can be directly formed on a FPC board, and the control circuit 42 is electrically connected to the plate capacitor via the FPC board. Furthermore, a surface of the non-single-crystal-silicon-based substrate 32 further comprises a TFT display area for displaying a variation of pressure detected by the capacitive semiconductor pressure sensor 30, thereby making it convenient for users to measure a variation of pressure and to observe measuring results.

In comparison with the prior art, the capacitive semiconductor pressure sensor of the present invention is formed on the non-single-crystal-silicon-based substrate, such as a glass substrate or a quartz substrate, so that prime costs of raw materials can be reduced considerably. Additionally, the diaphragm and its supporter of the present invention are composed of polysilicon, thereby reducing a production cost and avoiding forming epitaxial silicon that requires complicated steps and parameters. Moreover, the TFT control circuit and the thin film transistors in the TFT display area can be formed simultaneously in the present invention, thus effectively achieving process integration and reducing process steps.

Those skilled in the art will readily observe that numerous modifications and alterations of the device may be made while retaining the teachings of the invention. Accordingly, the above disclosure should be construed as limited only by the metes and bound of the appended claims.

1. A capacitive semiconductor pressure sensor comprising:
a non-single-crystal-silicon-based substrate;
a conductive movable polysilicon diaphragm;
a polysilicon supporter positioned on the non-single-crystal-silicon-based substrate for fixing two ends of the polysilicon diaphragm and forming a sealed cavity between the polysilicon diaphragm and the non-single-crystal-silicon-based substrate;
a stationary electrode positioned on the non-single-crystal-silicon-based substrate and below the polysilicon diaphragm, the stationary electrode and the polysilicon diaphragm constituting a plate capacitor; and
a thin film transistor (TFT) control circuit positioned on the non-single-crystal-silicon-based substrate and electrically connected to the plate capacitor.

2. The capacitive semiconductor pressure sensor of claim 1 wherein the non-single-crystal-silicon-based substrate is a glass substrate.

3. The capacitive semiconductor pressure sensor of claim 2 wherein the TFT control circuit is a low temperature polysilicon TFT control circuit.

4. The capacitive semiconductor pressure sensor of claim 1 wherein the non-single-crystal-silicon-based substrate is a quartz substrate.

5. The capacitive semiconductor pressure sensor of claim 4 wherein the TFT control circuit is a high temperature polysilicon TFT control circuit.

6. The capacitive semiconductor pressure sensor of claim 1 wherein the stationary electrode comprises aluminum (Al), titanium (Ti), platinum (Pt), or alloys.

7. The capacitive semiconductor pressure sensor of claim 1 wherein the polysilicon diaphragm and the polysilicon supporter are formed simultaneously.

8. The capacitive semiconductor pressure sensor of claim 1 wherein the polysilicon diaphragm is a doped polysilicon diaphragm.

9. The capacitive semiconductor pressure sensor of claim 1 wherein the non-single-crystal-silicon-based substrate further comprises a thin film transistor display region for displaying a variation of pressure detected by the capacitive semiconductor pressure sensor.

10. A capacitive semiconductor pressure sensor comprising:
an insulating substrate;
a conductive movable diaphragm;
a supporter positioned on the insulating substrate for fixing two ends of the diaphragm and forming a sealed cavity between the diaphragm and the insulating substrate;
a stationary electrode positioned on the insulating substrate and below the diaphragm; and
a control circuit electrically connected to the diaphragm and the stationary electrode.

11. The capacitive semiconductor pressure sensor of claim 10 wherein the stationary electrode comprises aluminum (Al), titanium (Ti), platinum (Pt), or alloys.

12. The capacitive semiconductor pressure sensor of claim 10 wherein the diaphragm and the supporter are formed simultaneously.

13. The capacitive semiconductor pressure sensor of claim 12 wherein the supporter comprises polysilicon.

14. The capacitive semiconductor pressure sensor of claim 13 wherein the diaphragm comprises a doped polysilicon icon.

15. The capacitive semiconductor pressure sensor of claim 10 wherein the diaphragm comprises a conductive material.

16. The capacitive semiconductor pressure sensor of claim 10 wherein the insulating substrate is a glass substrate.

17. The capacitive semiconductor pressure sensor of claim 16 wherein the control circuit is positioned on the glass substrate and the control circuit comprises a low temperature polysilicon thin film transistor control circuit.

18. The capacitive semiconductor pressure sensor of claim 10 wherein the insulating substrate is a quartz substrate.

19. The capacitive semiconductor pressure sensor of claim 18 wherein the control circuit is positioned on the quartz substrate and the control circuit comprises a high temperature polysilicon thin film transistor control circuit.

20. The capacitive semiconductor pressure sensor of claim 10 wherein the control circuit is positioned on a printed circuit board (PCB) and is electrically connected to the stationary electrode and the diaphragm via a flexible printed circuit (FPC) board.

21. The capacitive semiconductor pressure sensor of claim 10 wherein the control circuit is positioned on a flexible printed circuit (FPC) board, the control circuit being electrically connected to the stationary electrode and the diaphragm via the flexible printed circuit board.

22. The capacitive semiconductor pressure sensor of claim 10 wherein the insulating substrate further comprises a thin film transistor display region for displaying a variation of pressure detected by the capacitive semiconductor pressure sensor.
